(19) United States
(12) Patent Application Publication
(10) Pub. No.: US 2008/0108156 A1
(43) Pub. Date: May 8, 2008

(54) METHOD FOR FABRICATING LED LAMP AND HIGH-OUTPUT LED FABRICATED BY USING THE METHOD

(75) Inventors: Hak-geun JEONG, Daejeon (KR); Bong-man JUNG, Daejeon (KR); Soo-bin HAN, Daejeon (KR); Yu-jin SONG, Daejeon (KR); Suk-in PARK, Daejeon (KR); Seung-won YU, Daejeon (KR); Gyu-duk KIM, Daejeon (KR)

Correspondence Address: CANTOR COLBURN, LLP, 20 Church Street, 22nd Floor, Hartford, CT, 06103, US

(73) Assignee: KOREA INSTITUTE OF ENERGY RESEARCH, Daejeon (KR)

(21) Appl. No.: 11/624,028

(22) Filed: Jan. 17, 2007

(30) Foreign Application Priority Data
Nov. 7, 2006 (KR) 10-2006-0109602

(51) Int. Cl. H01L 21/00

(52) U.S. Cl. 438/22

(57) ABSTRACT

A method for fabricating a light emitting diode lamp in a simplified procedure, and a high-output LED, that has a simple structure and can exhibit improvement in heat release property, fabricated by using the method which includes the steps of coating an insulating layer on a substrate and etching the insulating layer using a mask pack, coating a conductive metal layer on the insulating layer, forming an electrode pattern and a recess, on which an LED chip is mounted, on the metal layer using the mask pack, attaching the LED chip to the top of the recess, connecting a wire to the electrode pattern, and mounting a reflector having a vertical opening hole around the LED chip on the substrate to reflect light emitted from the LED chip in all directions, and molding the top of the substrate from a transparent resin to cover the LED chip, the electrode pattern and the reflector.

This application claims priority to Korean Patent Application No. 10-2006-0109602, filed on Nov. 7, 2006, and all the benefits accruing therefrom under 35 U.S.C. §119, the contents of which are incorporated herein by reference in their entirety.

### BACKGROUND OF THE INVENTION

1. Field of the Invention

The present invention relates to a method for fabricating a light emitting diode lamp. More specifically, the present invention relates to a method for fabricating a light emitting diode lamp in a simplified procedure, and a high-output LED, that has a simple structure and can exhibit improvement in heat release property, fabricated by using the method.

2. Description of the Related Art

Light emitting diodes (hereinafter, referred to simply as “LEDs”) are formed of a variety of compound semiconductor materials (e.g., GsAs, AlGaAs, GaN etc.) acting as a light emitting source to emit light of various colors.

In recent years, developments in semiconductor techniques have brought about manufacture of LED products with higher luminance and superior quality.

As LEDs are widely applied to a variety of devices including displays and next-generation illumination sources, surface-mount LED devices are being commercially manufactured.

A general method for fabricating a high-output LED will be described below. As shown in FIG. 13, the method comprises forming an electrode pattern on a substrate 100 arranged an insulating layer 200, attaching a slug 300 to the top of the electrode pattern, mounting a reflector 400 having a top-opening on the slug 300, disposing an LED chip 500 on the reflector 400, connecting a wire 600 extended from the LED chip 500 to the electrode pattern, and molding the top of the substrate 100 with a transparent resin 700 to cover the LED chip 500 and the reflector 400 mounted on the substrate 100.

However, in the method for fabrication of a high-output LED, since an integrated-type reflector is used, to exert electric insulation and heat release efficiency, it is required that a slug be interposed between the electric pattern and the reflector, and that the reflector be accurately arranged on the center of the slug. As a result, the fabrication process is complicated. In addition, it takes for a long time to perform the complicated process.

Heat release property of LEDs is dependent on material properties of slugs. Accordingly, LEDs fabricated by using the method cannot exhibit uniform heat release property.

### SUMMARY OF THE INVENTION

In attempts to solve these problems, it is one object of the present invention to provide a method for fabricating a high-output light emitting diode (LED) in a simplified procedure by which a reflector having a bottom opening is used, and an LED chip is directly in contact with a substrate such that heat due to light emitted from an LED releases through the substrate.

It is another object of the present invention to provide a high-output LED, which has a simple structure and can exhibit improvement in heat release property, fabricated by using the method.

In accordance with one aspect of the present invention, there is provided a method for fabricating a high-output light emitting diode (LED), the method comprising the steps of: coating an insulating layer on a substrate and etching the insulating layer using a mask pack; coating a conductive metal layer on the insulating layer; forming an electrode pattern and a recess, on which an LED chip is mounted, on the metal layer using the mask pack; attaching the LED chip to the top of the recess, connecting a wire to the electrode pattern, and mounting a reflector having a vertical opening hole around the LED chip on the substrate to reflect light emitted from the LED chip in all directions; and molding the top of the substrate from a transparent resin to cover the LED chip, the electrode pattern and the reflector.

In accordance with another aspect of the present invention, there is provided high-output light emitting diode (LED) comprising a substrate; an insulating layer coated on the substrate and formed to have a predetermined pattern through an etching process; a metal layer coated on the substrate and formed through an etching process, and metal layer having an electrode pattern including a recess on which an LED chip is mounted; an LED chip inserted into the recess, directly mounted on top of the substrate, and connected to the electrode pattern through a wire; a reflector inserted into the recess, mounted around the LED chip, the reflector having a central vertical opening hole having a cross-section widened in an upward direction such that the reflector reflects light emitted from the LED chip in all directions; and a molding part molded from a transparent resin such that the LED chip, the electrode pattern and the reflector mounted on the substrate 2 are covered with the molding part.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view illustrating a high-output LED according to the present invention;

FIG. 2 is a cross-sectional view taken along the line A-A′ of FIG. 1;

FIG. 3 is an enlarged view of an area B in FIG. 2;

FIGS. 4 to 12 are cross-sectional views illustrating a method for fabricating a high-output LED according to the present invention, respectively; and

FIG. 13 is a cross-sectional view illustrating the structure of a general LED.

### DESCRIPTION OF THE PREFERRED EMBODIMENTS

Detailed description will be made of preferred embodiments of the present invention with reference to the accompanying drawings. However, various changes and modifications may be made to the preferred embodiments of the invention and the invention is not to be construed as being limited to the embodiments.

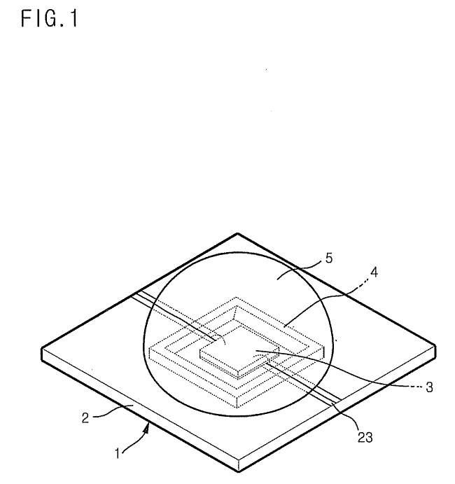

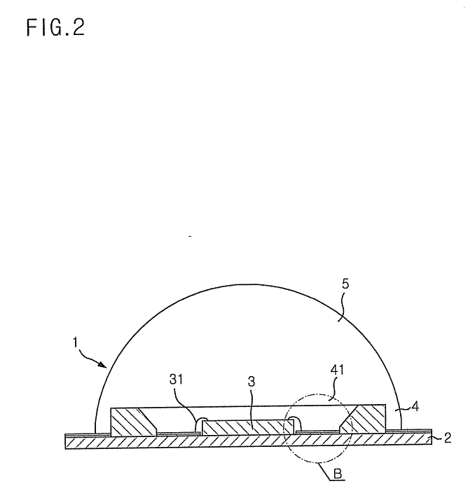

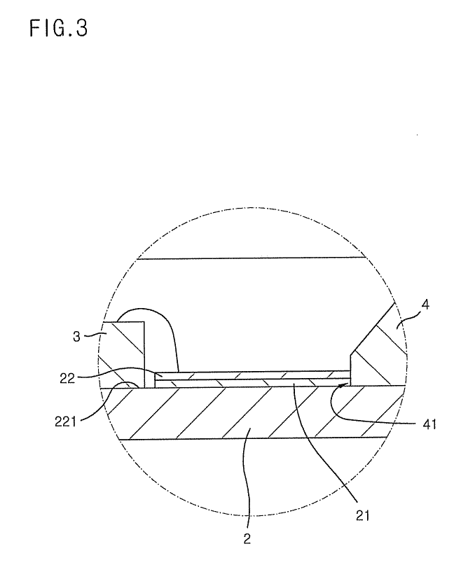

FIG. 1 is a perspective view illustrating a high-output LED according to the present invention. FIG. 2 is a cross-sectional view taken along the line A-A′ of FIG. 1. FIG. 3 is an enlarged view of an area B in FIG. 2.

As shown in FIGS. 1 to 3, a high-output LED 1 of the present invention includes a substrate 2, an insulating layer 21 coated on the substrate 2 and formed to have a predetermined pattern through an etching process. The high-output LED 1 also includes a metal layer 22 coated on the insulating layer 21 and formed to have a predetermined pattern through an etching process. The metal layer 22 has an electrode pattern including a recess on which an LED chip 3 is mounted. The LED chip 3 is inserted into the recess 221, is mounted on top of the substrate 2, and is connected to the electrode pattern through a wire 31. The high-output LED 1 also includes a reflector 4 inserted into the recess 221 and mounted around the LED chip 3. The reflector 4 has a central vertical opening hole having a cross-section widened in an upward direction such that it reflects light emitted from the LED chip in all directions. The high-output LED 1 also includes a molding part 5 molded from a transparent resin such that the LED chip 3, the electrode pattern 23 and the reflector 4 mounted on the substrate 2 are covered with the molding part 5.

The substrate 2 may be an aluminum substrate or silicon wafer that can be commonly used in the art.

According to an embodiment of the present invention, the insulating layer 21 is coated on the substrate 2 and has a predetermined pattern through an etching process. The insulating layer pattern can be obtained by etching through a mask. Since the etching is commonly used in flexible circuit substrate manufacture or semiconductor fabrication, detailed description thereof will be omitted herein.

The metal layer 22 formed on the insulating layer 21 through a coating process acts as an electrode supplying an electric power to the LED chip 3.

According to an embodiment of the present invention, the metal layer 22 is preferably made of high conductive metal, e.g., copper (Cu), aluminum (Al) or silver (Ag).

The metal layer 22 supplying an electric power to the LED chip 3 as described above is formed in the same manner as the case of the insulting layer 21. The metal layer 22 has the recess 221 on which the LED chip 3 is mounted. The wire 31 extended from the LED chip 3 connects the LED chip 3 to the electrode pattern 23.

According to an embodiment of the present invention, the LED chip 3 is an element that emits light. Light emission mechanism thereof is as follows. After junction of P-type semiconductor and N-type semiconductor, a forward current is applied to cause recombination of electrons with holes in a junction layer between the two semiconductors. At this time, stabilization energy for the recombination is radiated in the form of light.

The LED chip 3 is formed of a compound, e.g., GaAs, AlGaAs, GaN etc., to emit a variety of light. The LED chip 3 is widely used for home and office appliances including display lamps and displays.

According to another embodiment of the present invention, the reflector 4 may have a square or circle structure. The reflector 4 is inserted into the LED chip 3 and mounted on the substrate 2. The reflector 4 includes a central vertical opening hole 41 having a cross-section widened in an upward direction so that it can reflect light emitted from the LED chip 3 in all directions.

The molding part 5 is molded from a transparent resin such that the LED chip 3, the electrode pattern 23 and the reflector 4 mounted on the substrate 2 are covered with the molding part 5. The transparent resin may be an epoxy or acryl resin. Preferred is the acryl resin.

The epoxy resin has a specific gravity of 1.230 to 1.189 and is superior in mechanical properties such as bending strength and hardness. Also, formation of volatile material and reduction in volume does not occur upon hardening of the epoxy resin. The epoxy resin has a superior adhesivity to a subject surface.

Since the epoxy resin is excellent in sealability, moldability, and embeddability, it is most suitable for use in joining metals together.

The epoxy resin exhibits excellent electrical insulating property in electronic devices, thus preventing escape of heat emitted from the LED chip 3.

In the high-output LED 1 of the present invention, since the LED chip 3 emitting light derived from external power is directly mounted on the substrate 2, it releases heat, which is generated during light-emission of the LED, through the substrate 2, thus enabling improvement in heat release performance.

In general methods for fabrication of LEDs, it is required that a plug be mounted under a reflector, to realize desired electric insulation and heat release. In contrast, in the method of the present invention, an LED can be easily manufactured in a simple manner without using any plug. That is, the insulating layer 21 and the metal layer 22 are sequentially formed on the substrate 2 by using coating and etching processes. Then, the LED chip is directly mounted on the substrate. The reflector 4 having a bottom opening is inserted into the LED chip 3 and mounted on the substrate 2. Lastly, the resulting structure is molded from a transparent resin.

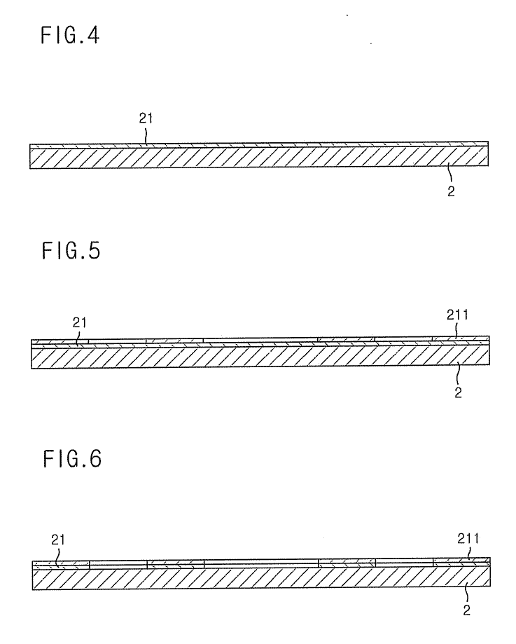

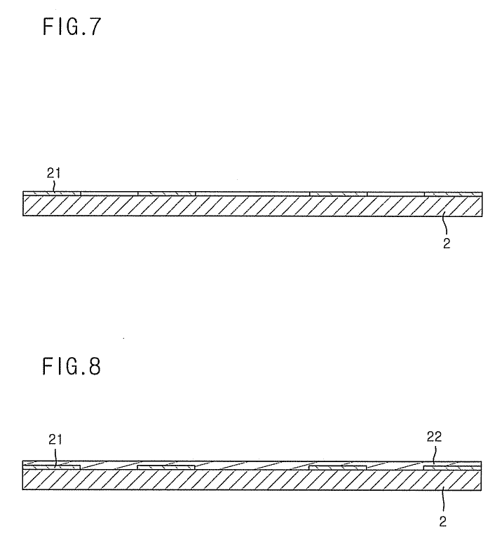

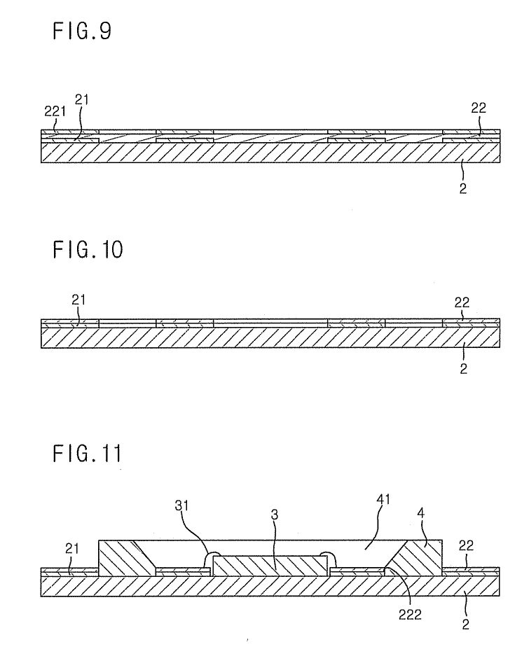

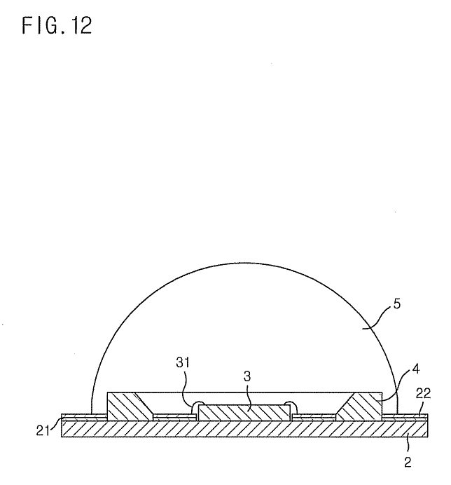

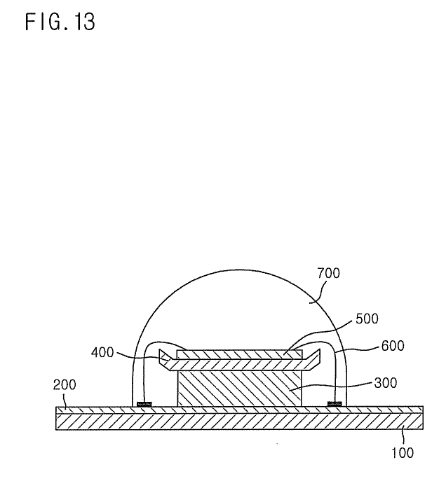

Hereinafter, a method for fabricating the high-output LED of the present invention will now be described in greater detail with reference to FIGS. 4 to 12.

FIGS. 4 to 12 are cross-sectional views illustrating a method for fabricating the high-output LED according to the present invention.

First, an insulating layer 21 is coated on the top of a substrate 2, and a mask having a predetermined pattern is then arranged on the top of the insulating layer 21.

The mask is subjected to well-known etching to remove the mask from the insulating layer 21, thereby forming a predetermined pattern on the insulating layer 21.

A conductive metal layer 22 is coated on the insulating layer 21. The mask having a predetermined pattern is arranged on the metal layer 22.

The resulting structure is etched to remove the mask from the metal layer 22, thereby obtaining a metal layer 22 including a recess 221 on which an electrode pattern 23 and an LED chip 3 are mounted in the form of a predetermined pattern.

The LED chip 3 is directly attached to the recess 221, and a wire 31 extended from the LED chip 3 is connected to the electrode pattern 23.

A reflector 4 having a bottom-opening is arranged such that it is mounted around the LED chip 3. Lastly, the electrode pattern 23 and the reflector 4 mounted on the substrate 2 are molded from a transparent resin such that they are covered with the resin.

As apparent from the foregoing, according to the method of the present invention, a high-output LED can be manufactured in a simplified procedure by which an LED chip is directly in contact with a substrate without using any slug, and a reflector having a bottom-opening is combined with the substrate. Accordingly, the use of the method ensures a high-output LED having a simple structure.

Since heat due to light emitted from the LED directly is released through the substrate, the high-output LED can exhibit improvement in heat release property, as compared to general LEDs.

Although the present invention has been described herein in detail with reference to its preferred embodiments, those skilled in the art will appreciate that these embodiments do not serve to limit the invention and that various changes and modifications may be made thereto without departing from the spirit and scope of the invention as defined in the appended claims.

What is claimed is:

1. A method for fabricating a high-output light emitting diode (LED), the method comprising the steps of:
coating an insulating layer on a substrate and etching the insulating layer using a mask pack;
coating a conductive metal layer on the insulating layer;
forming an electrode pattern and a recess, on which an LED chip is mounted, on the metal layer using the mask pack;
attaching the LED chip to the top of the recess, connecting a wire to the electrode pattern, and mounting a reflector having a vertical opening hole around the LED chip on the substrate to reflect light emitted from the LED chip in all directions; and
molding the top of the substrate from a transparent resin to cover the LED chip, the electrode pattern and the reflector.

2. The method according to claim 1, wherein the metal layer is made of copper (Cu).

3. A high-output light emitting diode (LED) comprising:
a substrate;
an insulating layer coated on the substrate and formed to have a predetermined pattern through an etching process;
a metal layer coated on the substrate and formed through an etching process, and the metal layer having an electrode pattern including a recess on which an LED chip is mounted;
an LED chip inserted into the recess, directly mounted on top of the substrate, and connected to the electrode pattern through a wire;
a reflector inserted into the recess, mounted around the LED chip, the reflector having a central vertical opening hole having a cross-section widened in an upward direction such that the reflector reflects light emitted from the LED chip in all directions; and
a molding part molded from a transparent resin such that the LED chip, the electrode pattern and the reflector mounted on the substrate 2 are covered with the molding part.

4. The method according to claim 3, wherein the metal layer is made of copper (Cu).
